(19) United States
(12) Patent Application Publication
(10) Pub. No.: US 2011/0025367 A1
(43) Pub. Date: Feb. 3, 2011

(54) ENERGY FEEDBACK DEVICE FOR THE WARM-UP TEST OF A POWER SUPPLY

(75) Inventors: Chi Chun LI, Taipei County (TW); Yung Han, Taipei County (TW)

Correspondence Address: RABIN & Berdo, PC, 1101 14TH STREET, NW, SUITE 500, WASHINGTON, DC, 20005, US

(73) Assignee: HERO BEAR ANIMATION CO., LTD., Taipei County (TW)

(21) Appl. No.: 12/729,568

(22) Filed: Mar. 23, 2010

(30) Foreign Application Priority Data
Jul. 29, 2009 (TW) 098125594

(51) Int. Cl. G01R 31/40

(52) U.S. Cl. 324/764.01

(57) ABSTRACT

This invention relates to an energy feedback device for the warm-up test of a power supply, which includes a power supply, a current limiter, a transformer and a selector. Moreover, the power supply is a target load tested by a warm-up procedure; external input power enters the selector, and the other end of the selector is electrically connected to the power supply. The current limiter is used to adjust the warm-up power consumed by the load of the power supply under testing. One end of the current limiter is electrically connected to another end of the power supply, and another end of current limiter is electrically connected with the voltage adapter; and another end of the voltage adapter is electrically connected to another end of the selector. Therefore, the device of this invention can effectively provide enhancing the efficiency of power is consumption, over-current protection and multiple application of energy feedback.

### TECHNICAL FIELD OF THE INVENTION

This invention relates to an energy feedback device for the warm-up test of a power supply. It specifically relates to a combination of hardware components of a current limiter, a voltage adapter and a selector. Hence, this invention features over-current protection, effective enhancing of energy utilization efficiency and energy feedback, etc. Therefore, it is suitable to be applied to an energy feedback device for the warm-up test of a power supply or other similar devices.

### PRIOR ART

When it comes to the prior art applied to the warm-up test of a power supply, the output terminal of power supply is usually connected is to the warm-up load resistor directly (please refer to FIG. 1) so as to provide the hardware structure for the warm-up test of a power supply 1. This method can complete the warm-up test of a power supply 1. However, a high percentage of electrical energy is inevitably wasted (mostly in the form of heat) in the resistor that acts as warm-up load. Therefore, the efficiency of the energy utilization cannot be effectively enhanced and energy feedback cannot be provided. Also, too much precious energy is lost in vain. Thus, the warm-up test of a power supply needs to be improved.

### BACKGROUND OF THE INVENTION

The main objective of this invention is to provide an energy feedback device for warm-up test of a power supply. It is a design that provides voltage conversion through a voltage adapter which is installed between the current limiter and the selector. During the warm-up test, the output power of a power supply will pass through current limiter, the voltage adapter and then enter the selector. After that, selector will perform automatic switching according to the output value of the voltage adapter to select whether the needed input power for the warm-up test of the power supply should be supplied from the external power or from the stored and converted electrical energy in the voltage adapter. By doing so, the power supplied from the external power can be effectively saved, and its entire practical function can be enhanced.

Another objective of the current invention is to provide an energy feedback device for the warm-up test of a power supply. Through the voltage adapter, it can be further connected to an electrical appliance (electrical appliance can be a water heater, indoor air-conditioner, etc.) so that the majority of additionally consumed energy (for example, thermal energy and electrical energy, etc.) during the warm-up test can be provided to the electrical appliance through the voltage adapter for energy feedback. Therefore, energy utilization efficiency can be enhanced, and the energy used to be ignored and wasted can be utilized in more practical application.

Another objective of this invention is to provide an energy feedback device for the warn-up test of power supply. Because one end of the current limiter is electrically connected to the power supply, it can avoid output current surge from the power supply. As a result, it can both enhance the operation efficiency of the voltage adapter and the safety of the device of the present invention.

To achieve the above mentioned objectives, this invention is an energy feedback device for warm-up test of a power supply, which includes a power supply, a selector, a current limiter and a voltage adapter. The power supply is an electrical product ready to be used with a warm-up test; the external input power will be sent into this energy feedback device through the selector, and one end of the selector is electrically connected to one end of the power supply; the is current limiter is to adjust the warm-up efficiency of the power supply, and one end of the current limiter is electrically connected to the other end of the power supply, and another end of the current limiter is electrically connected to the voltage adapter; and another end of the voltage adapter is electrically connected to one end of the selector. By following this hardware structure, the warm-up test for a power supply is then performed, and during the warm-up test, the energy utilization efficiency can be effectively enhanced, over-current protection and energy feedback can be provided. That is, the present invention meets the global trend of energy saving and environmental protection, and provides a better application in energy feedback from the warm-up test of a power supply.

### PREFERRED EMBODIMENTS

Please refer to figures from 1 to 4, which shows that the current invention is an energy feedback device for the warm-up test of a power supply, which includes:

a power supply 10, wherein the power supply 10 is an electric product ready to be used with a warm-up test.

a selector 20, and an external input power is sent into this energy feedback device through the selector 20; another end of the selector 20 is electrically connected to one end of the power supply 10.

a current limiter 30, one end of the current limiter 30 is electrically connected to another end of the power supply 10; wherein the current limiter 30 is adjustable by the demand.

a voltage adapter 40, voltage adapter 40 provides functions of voltage conversion and electrical energy saving, and one end of the voltage adapter 40 is electrically connected to another end of the current limiter 30, and another end of the voltage adapter 40 is electrically connected to another end of the selector 20; wherein the voltage adapter 40 is adjustable and works as a transformer from DC to DC, from AC to DC, or from DC to AC.

Therefore, during the warm-up test of a power supply 10, energy utilization efficiency can be effectively enhanced, and over-current protection as well as energy feedback can be provided. Then, the present invention meets the global trend of energy saving and provides a better solution in environmental protection.

Furthermore, the voltage adapter 40 can be further connected to an electrical appliance 50 (electrical appliance 50 can be a water heater and indoor air-conditioner, etc.) so as to provide the additionally consumed energy (used to be ignored and wasted in prior application) during the warm-up test (for example, thermal energy, electrical energy, etc.), through the voltage adapter 40, to the electrical appliance for energy feedback and/or diversified is application.

Through the above combination, an energy feedback device for the warm-up test of a power supply is formed. Please refer to FIGS. 1˜4, as can be seen, the main feature of the current invention is to provide an energy feedback device for the warm-up test of a power supply, which includes a structural combination of a power supply 10, a selector 20, a current limiter 30 and a voltage adapter 40; one end of the current limiter 30 is electrically connected to power supply 10 so as to avoid output current surge from the power supply 10 and to increase the efficiency of the voltage adapter 40. In addition, through the voltage adapter 40 installed between the current limiter 30 and selector 20, the voltage conversion and electrical energy storage is then achieved. As soon as the output voltage of the transformed and restored power supplied by the voltage adapter 40 is greater than the external voltage input to the power supply 10, the selector 20 will automatically perform the switching, and the voltage adapter 40 take a turn to provide the power needed for the warm-up test of the power supply 10. When the power supplied by the voltage adapter 40 approaches the input voltage of power supply 10, the selector 20 will automatically perform a switching to select whether external power source or the converted and stored electrical energy from the voltage adapter 40 will supply the electric energy to the power supply 10. When the power supplied by the voltage adapter 40 is lower than the input voltage power supply 10 needs, the selector 20 will automatically perform a back switching to select the external power source. Therefore, the entire power can then be effectively saved. Moreover, the voltage adapter 40 can be further connected to an electrical appliance 50 (the electrical appliance 50 can be a water heater or indoor air-conditioner, etc.) so as to put those saved energy into more diversified utilization.

In short, the present invention provides an energy feedback device, over-current protection, higher energy conversion efficiency. And, electric energy used to be wasted and ignored can be put into more practical and diversified energy application in our global environment.

However, the above mentioned explanation is only some better embodiments of the current invention, which should not be used to limit the scope of the current invention; therefore, any equivalent change or revision based on “what is claimed” and patent specification should all be included in the current invention.

### BRIEF DESCRIPTIONS OF THE DRAWINGS

FIG. 1 is a schematic diagram of the prior art.

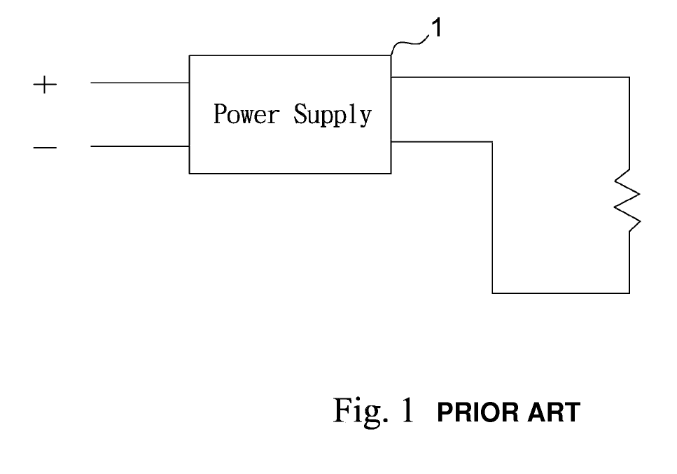

FIG. 2 is a schematic diagram of the current invention.

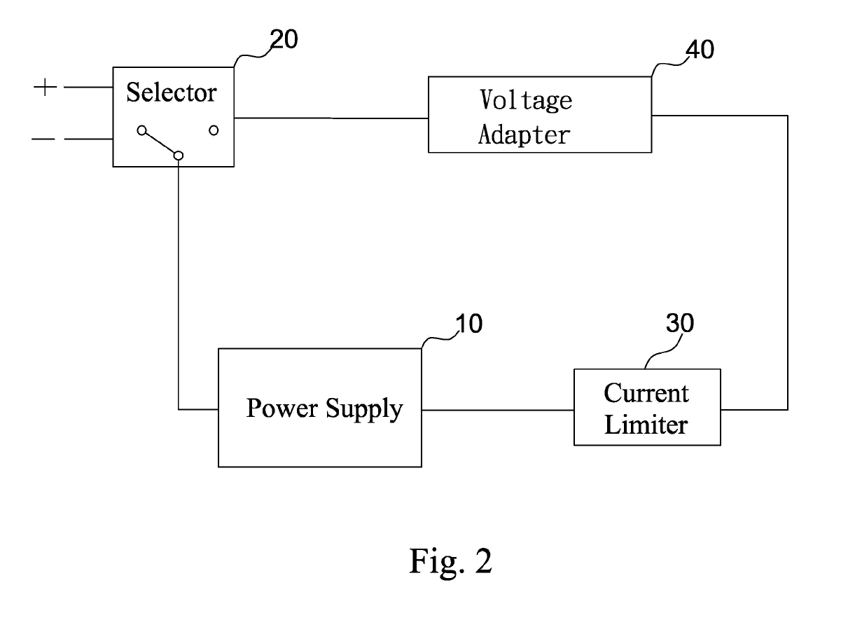

FIG. 3 is also a schematic diagram of the current invention.

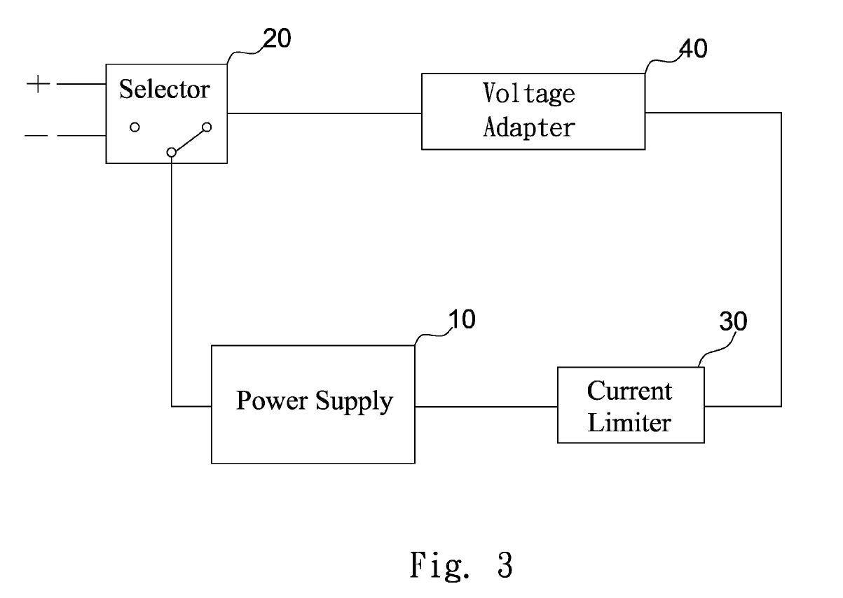

FIG. 4 is another schematic diagram of the current invention.

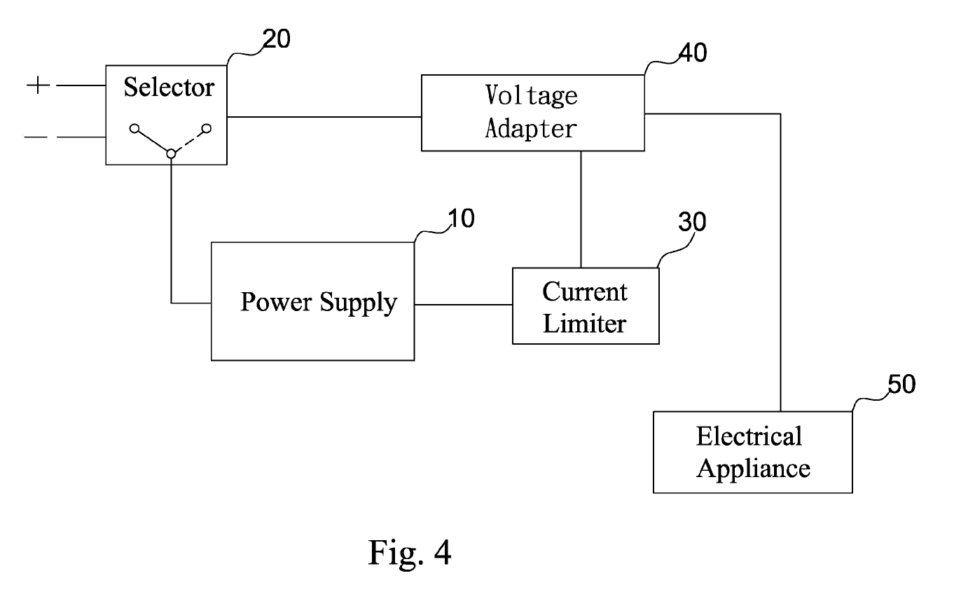

### SYMBOL DESCRIPTIONS OF THE MAJOR COMPONENTS

| | | | |
|---|---|---|---|
| 1 | Power supply | 10 | Power supply |
| 20 | Selector | 30 | Current limiter |
| 40 | Voltage adapter | 50 | Electrical appliance |

What is claimed is:

1. An energy feedback device for the warm-up test of a power supply containing:
a power supply, wherein the power supply is the target device under a warm-up test;
a selector, wherein the external input power for warm-up test is connected through the selector, and one end of the selector is electrically connected to one end of the power supply;
a current limiter, wherein one end of the current limiter is electrically connected to another end of the power supply; and
a voltage adapter, wherein one end of the voltage adapter is electrically connected to another end of the current limiter, and another end of the voltage adapter is electrically connected to another end of the selector.

2. An energy feedback device for the warm-up test of a power supply according to claim 1, the current limiter is adjustable.

3. An energy feedback device for the warm-up test of a power supply according to claim 1, the voltage adapter is adjustable.

4. An energy feedback device for the warm-up test of a power supply according to claim 1, the voltage adapter is further connected to an electrical appliance.

5. An energy feedback device for the warm-up test of a power supply according to claim 3, the voltage adapter is further connected to an electrical appliance.

6. An energy feedback device for the warm-up test of a power supply according to claim 4, the electrical appliance connected to the voltage adapter is a water heater.

7. An energy feedback device for the warm-up test of a power supply according to claim 4, wherein the electrical appliance connected to the voltage adapter is an air-conditioner.
